(19) United States
(12) Patent Application Publication
(10) Pub. No.: US 2014/0209282 A1
(43) Pub. Date: Jul. 31, 2014

(54) HEAT DISSIPATION APPARATUS FOR EXPANSION BASE

(71) Applicant: HON HAI PRECISION INDUSTRY CO., LTD., New Taipei (TW)

(72) Inventors: CHIH-HANG CHAO, New Taipei (TW); WEI-CHENG CHENG, New Taipei (TW)

(73) Assignee: HON HAI PRECISION INDUSTRY CO., LTD., New Taipei (TW)

(21) Appl. No.: 14/050,542

(22) Filed: Oct. 10, 2013

(30) Foreign Application Priority Data
Jan. 29, 2013 (TW) 102103377

(51) Int. Cl. H05K 7/20

(52) U.S. Cl. CPC H05K 7/20136
USPC 165/121

(57) ABSTRACT

A heat dissipation apparatus includes an expansion base, an air duct, a fan, and a portable device. An air inlet slot, a first inserting slot, and a second inserting slot are defined in the expansion base. The air duct is inserted in the first inserting slot. A first air inlet opening and a plurality of diagonal air outlet slots are defined in the air duct. The portable device is inserted in the second inserting slot. A first airflow passage is defined between the air inlet slot, the fan, the first air inlet opening, the air duct, and the plurality of air outlet slots. The fan is adapted to generate airflow through the portable device in such a manner that airflow flows from the expansion base outside is sucked into and blown out of the air duct via the first airflow passage.

### BACKGROUND

1. Technical Field

The present disclosure relates to a heat dissipation apparatus for an expansion base in portable devices.

2. Description of Related Art

Panel computers include expansion bases to insert expansion cards. However, panel computers generate large amounts of heat when connected to expansion bases, which may be a hazard and cause a reduction in the life of the panel computers.

Therefore, there is a need for improvement in the art.

### BRIEF DESCRIPTION OF THE DRAWINGS

Many aspects of the embodiments can be better understood with reference to the following drawings. The components in the drawings are not necessarily drawn to scale, the emphasis instead being placed upon clearly illustrating the principles of the embodiments. Moreover, in the drawings, like reference numerals designate corresponding parts throughout the several views.

FIG. 1 is an isometric, exploded view of an embodiment of a heat dissipation apparatus for an expansion base.

FIG. 2 is an enlarged view of a circled portion II of FIG. 1.

FIG. 3 is an assembled view of the heat dissipation apparatus for an expansion base of FIG. 1.

FIG. 4 is a cross-sectional view of the heat dissipation apparatus for an expansion base of FIG. 3, taken along line IV-IV.

### DETAILED DESCRIPTION

The disclosure is illustrated by way of example and not by way of limitation in the figures of the accompanying drawings in which like references indicate similar elements. It should be noted that references to “an” or “one” embodiment in this disclosure are not necessarily to the same embodiment, and such references mean “at least one.”

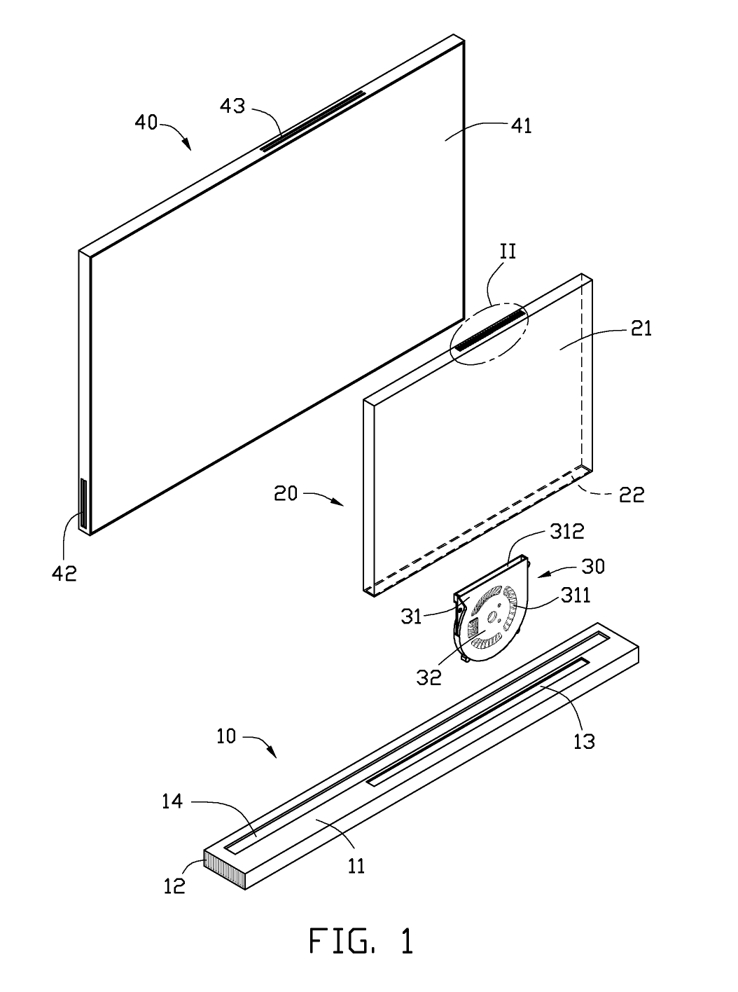

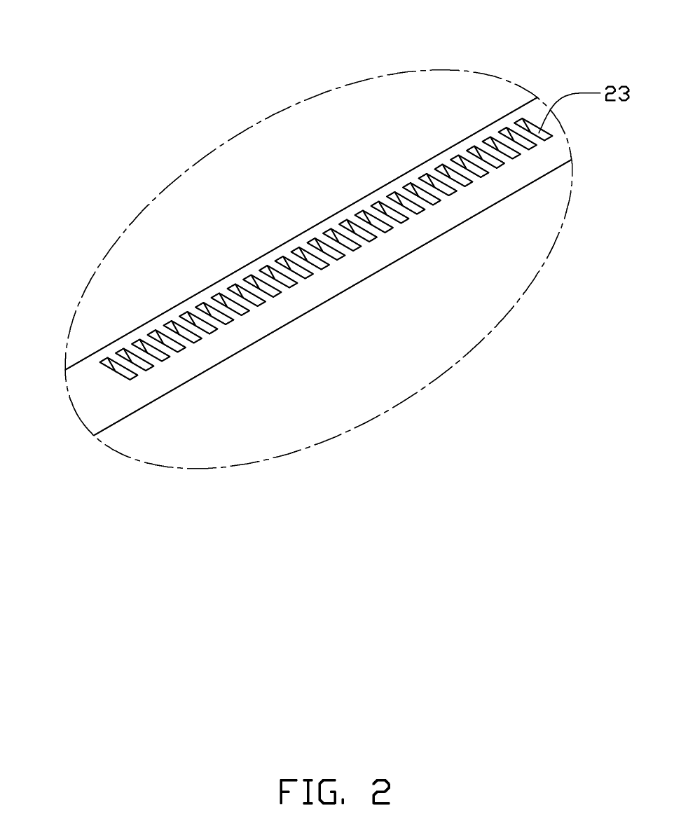

FIGS. 1 and 2 show a heat dissipation apparatus, which includes an expansion base 10, an air duct 20, a fan 30, and a portable device 40.

The expansion base 10 includes a base body 11. A plurality of air inlet slots 12 is defined in one side of the base body 11. A first inserting slot 13 and a second inserting slot 14 are defined in a top of the base body 11. The first inserting slot 13 is substantially parallel to the second inserting slot 14.

The air duct 20 includes a duct body 21. A first air inlet opening 22 is defined in a bottom of the duct body 21. A plurality of air outlet slots 23 is diagonally defined in a top of the duct body 21. A first air inlet channel defined by the first air inlet opening 22 is substantially parallel to a first air outlet channel defined by the plurality of air outlet slots 23. The first air inlet opening 22 communicates with the plurality of air outlet slots 23. In this embodiment, a length of the first inserting slot 13 is less than a length of the second inserting slot 14. A length of the first inserting slot 13 is substantially equal to a length of the duct body 21, and a width of the first inserting slot 13 is substantially equal to a thickness of the duct body 21. A length of the second inserting slot 14 is substantially equal to a length of the portable device 40, and a width of the second inserting slot 14 is substantially equal to a thickness of the portable device 40.

The fan 30 includes a shell 31 and a rotatable fan blade module 32. A second air inlet opening 311 is defined in one side of the shell 31. The shell 31 further defines a second air outlet opening 312 in a top of the shell 31. The second air inlet opening 311 allows air to flow into the fan 30 along a first direction, which is in line with a rotating axle of the fan blade module 32. The second air outlet opening 312 allows air to flow out of the fan 30 along a second direction, which is substantially perpendicular to the first direction. In this embodiment, a length of the second air outlet opening 312 is substantially equal to a length of the plurality of air outlet slots 23.

The portable device 40 includes a main body 41. Two third air inlet openings 42 are defined in one side of the main body 41. Two third air outlet openings 43 are defined in a top of the main body 41. A second air inlet channel defined by the two third air inlet openings 42 is substantially perpendicular to a second air outlet channel defined by the two third air outlet openings 43. The two third air inlet openings 42 communicate with the two third air outlet openings 43.

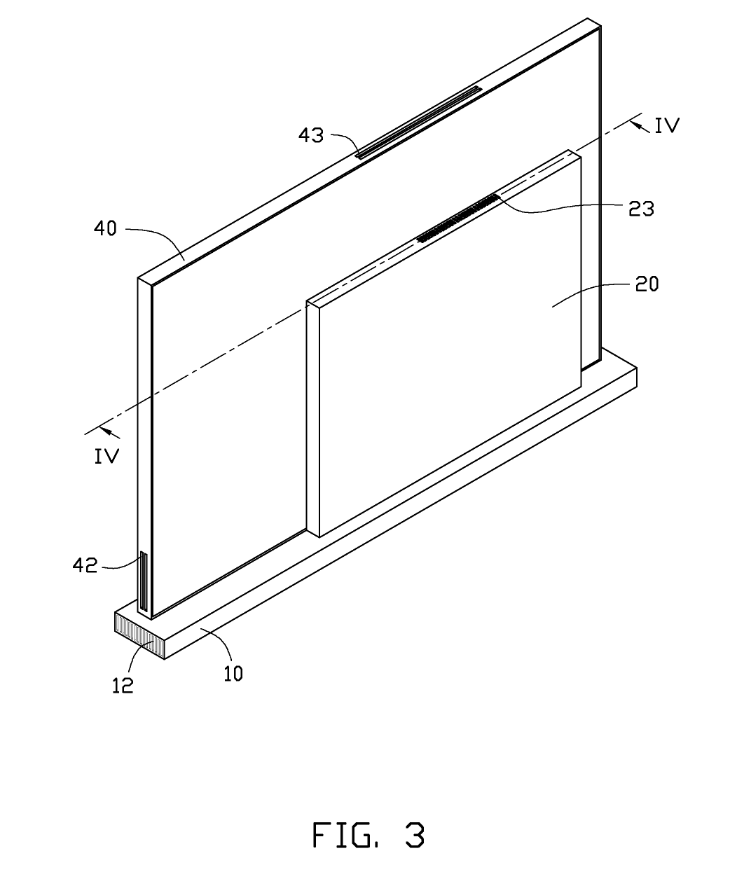

FIGS. 1 to 3 show that in assembly, the fan 30 is fixed in the duct body 21 of the air duct 20, such that the second air outlet opening 312 of the fan 30 is aligned with the plurality of air outlet slots 23 of the duct body 21. The duct body 21 is partly received in the first inserting slot 13, such that the first air inlet opening 22 communicates with the first inserting slot 13. The portable device 40 is received in the second inserting slot 14. A back surface of the portable device 40 abuts against the duct body 21. The plurality of air outlet slots 23 faces the back of the portable device 40.

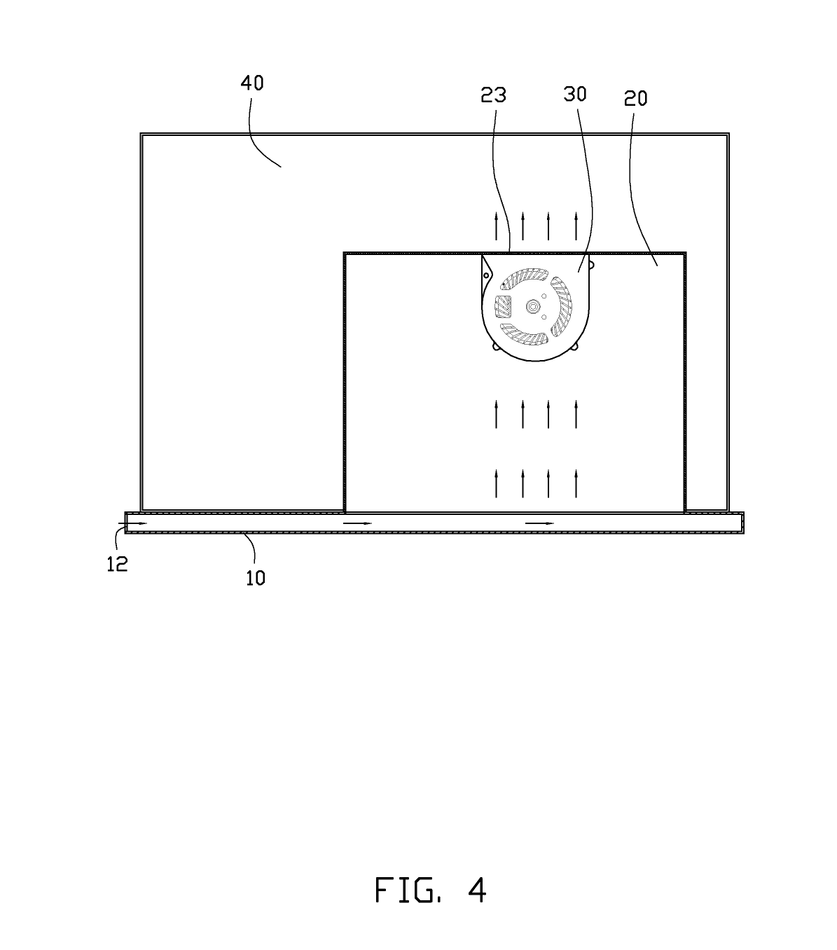

FIG. 4 shows that in operation, the portable device 40 generates large amounts of heat when powered on. A first amount of air from outside the expansion base 10 is sucked into the portable device 40 via the two third air inlet openings 42 or the two third air outlet openings 43. The first amount of air displaces heated air in the portable device 40 and exits the portable device 40 through the two third air inlet openings 42 or the two third air outlet openings 43. A second amount of air from outside the expansion base 10 is sucked into the fan 30 via the plurality of air inlet slots 12 and the second air inlet opening 311. A speed of the second amount of air is increased when passing through the fan 30. The second amount of air is blown out of the fan 30 through the second air outlet opening 312 toward the plurality of air outlet slots 23 of the air duct 20. The second amount of air is diagonally blown out of the air duct 20 through the plurality of air outlet slots 23. The second amount of air is blown toward the back of the portable device 40 to remove the heat accumulated on the portable device 40. Therefore, a temperature of the portable device 40 is further decreased.

In this embodiment, the duct body 21 of the air duct 20 is made of heat-conducting material. The heat accumulated on the back of the portable device 40 is partially transmitted to the duct body 21. The second amount of air that passes through the duct body 21 removes the heat accumulated on the duct body 21. Therefore, utilizing the three described modes of heat dissipation, the heat dissipation efficiency of the heat dissipation apparatus is significantly improved.

Using a software application called ICEPAK to simulate the efficiency of the heat dissipation apparatus, the following results of an embodiment shown below were obtained. The simulated conditions were set as follows: a power dissipation of a CPU of the portable device 40 is 2 watts (W). A power dissipation of a memory of the portable device 40 is 1.5 W. A power dissipation of a power control unit of the portable device 40 is 0.6 W. The fan 30 has a dimension of 92 millimeters (mm)×92 mm×25 mm (length×width×height). A maximum air flow rate of the fan 30 is 35.32 cubic feet per minute (cfm). A rated speed of the fan 30 is 2000 revolutions per minute (rpm). A maximum static pressure of the fan 30 is 0.084 inch-H₂O.

The simulation according to the set conditions shows that when using the heat dissipation apparatus of the disclosure, a maximum temperature of the back of the portable device 40 is 43.2 degrees Celsius, a maximum temperature of the CPU and the memories is 95.3 degrees Celsius, and a maximum temperature of the power control unit is 96.5 degrees Celsius. In contrast, when using another heat dissipation apparatus, a maximum temperature of the back of the portable device 40 is 48.5 degrees Celsius, a maximum temperature of the CPU and the memory is 99.4 degrees Celsius, and a maximum temperature of the power control unit is 100.8 degrees Celsius. As can be seen, the maximum temperature of the portable device 40 is largely decreased and heat dissipation efficiency is improved.

Even though numerous characteristics and advantages of the present disclosure have been set forth in the foregoing description, together with details of the structure and function of the disclosure, the disclosure is illustrative only, and changes may be made in detail, especially in the matters of shape, size, and the arrangement of parts within the principles of the disclosure to the full extent indicated by the broad general meaning of the terms in which the appended claims are expressed.

What is claimed is:

1. A heat dissipation apparatus, comprising:
an expansion base comprising a base body, an air inlet slot defined at one side of the base body, a first inserting slot and a second inserting slot defined at a top of the base body;
an air duct inserted in the first inserting slot; the air duct comprises a duct body, a first air inlet opening defined at a bottom of the duct body, a plurality of air outlet slots defined diagonally across a top of the duct body;
a fan fixed in the duct body; and
a portable device configured to be inserted in the second inserting slot; wherein a first airflow passage is defined between the air inlet slot, the fan, the first air inlet opening, the air duct, and the plurality of air outlet slots; the fan is adapted to generate airflow through the portable device in such a manner that airflow flows from the expansion base outside is sucked into and blown out of the air duct via the first airflow passage.

2. The heat dissipation apparatus of claim 1, wherein the fan comprises a shell and a rotatable fan blade module; a second air inlet opening is defined at one side of the shell; and a second air outlet opening is defined at a top of the shell.

3. The heat dissipation apparatus of claim 2, wherein the second air inlet opening allows air to flow in a first direction which is in line with a rotating axle of the fan blade module; and the second air outlet opening allows air to flow in a second direction which is substantially perpendicularly to the first direction.

4. The heat dissipation apparatus of claim 3, wherein a length of the second air outlet opening is equal to a length of the plurality of air outlet slots.

5. The heat dissipation apparatus of claim 4, wherein the portable device comprises a main body, a third air inlet opening defined at one side of the main body, a third air outlet opening defined at a top of the main body; a second airflow passage is defined between the third air inlet opening and the third air outlet opening; the portable device is adapted to guide airflow in and out of the portable device via the second airflow passage.

6. The heat dissipation apparatus of claim 5, wherein the air duct further comprises a first air inlet channel defined by the first air inlet opening and a first air outlet channel defined by the plurality of air outlet slots, the first air inlet channel being substantially parallel to the first air outlet channel; the portable device further comprises a second air inlet channel defined by the third air inlet opening and a second air outlet channel defined by the third air outlet opening, the second air inlet channel being substantially perpendicularly to the second air outlet channel.

7. The heat dissipation apparatus of claim 5, wherein the first air inlet opening is communicated with the plurality of air outlet slots; and the third air inlet opening is communicated with the third air outlet opening.

8. The heat dissipation apparatus of claim 7, wherein a length of the first inserting slot is less than that of the second inserting slot; a length of the first inserting slot is equal to that of the duct body; a width of the first inserting slot is equal to a thickness of the duct body; a length of the second inserting slot is equal to that of the portable device; and a width of the second inserting slot is equal to a thickness of the portable device.

9. A heat dissipation apparatus, comprising:
an expansion base defining an air inlet slot at one side of the expansion base and a first inserting slot and a second inserting slot at a top of the base body;
an air duct inserted in the first inserting slot; the air duct defines a first air inlet opening at a bottom of the air duct and a plurality of air outlet slots defined diagonally across a top of the air duct;
a fan fixed in the air duct; a second air inlet opening and a second air outlet opening are defined in the fan; and
a portable device configured to be inserted in the second inserting slot; wherein a first airflow passage is defined between the air inlet slot, the second air inlet opening, the fan, the second air outlet opening, the first air inlet opening, the air duct, and the plurality of air outlet slots; the fan is adapted to generate airflow through the portable device in such a manner that airflow flows from the expansion base outside is sucked into and blown out of the air duct via the first airflow passage.

10. The heat dissipation apparatus of claim 9, wherein the fan comprises a shell and a rotatable fan blade module; the second air inlet opening is defined at one side of the shell; and the second air outlet opening is defined at a top of the shell.

11. The heat dissipation apparatus of claim 10, wherein the second air inlet opening allows air to flow in a first direction which is in line with a rotating axle of the fan blade module; and the second air outlet opening allows air to flow in a second direction which is substantially perpendicularly to the first direction.

12. The heat dissipation apparatus of claim 11, wherein a length of the second air outlet opening is equal to a length of the plurality of air outlet slots.

13. The heat dissipation apparatus of claim 12, wherein the portable device comprises a main body, a third air inlet opening defined at one side of the main body, a third air outlet opening defined at a top of the main body; a second airflow passage is defined between the third air inlet opening and the third air outlet opening; the portable device is adapted to guide airflow in and out of the portable device via the second airflow passage.

14. The heat dissipation apparatus of claim 13, wherein the air duct further comprises a first air inlet channel defined by the first air inlet opening and a first air outlet channel defined by the plurality of air outlet slots, the first air inlet channel being substantially parallel to the first air outlet channel; the portable device further comprises a second air inlet channel defined by the third air inlet opening and a second air outlet channel defined by the third air outlet opening, the second air inlet channel being substantially perpendicularly to the second air outlet channel.

15. The heat dissipation apparatus of claim 13, wherein the first air inlet opening is communicated with the plurality of air outlet slots; and the third air inlet opening is communicated with the third air outlet opening.

16. The heat dissipation apparatus of claim 15, wherein a length of the first inserting slot is less than a length of the second inserting slot; a length of the first inserting slot is equal to a length of the duct body; a width of the first inserting slot is equal to a thickness of the duct body; a length of the second inserting slot is equal to a length of the portable device; and a width of the second inserting slot is equal to a thickness of the portable device.
